(19) United States
(12) Patent Application Publication
(10) Pub. No.: US 2026/0282872 A1
(43) Pub. Date: Sep. 17, 2026

(54) SUBTRACTIVE INTERCONNECT STRUCTURE WITH TOP VIA

(71) Applicant: INTERNATIONAL BUSINESS MACHINES CORPORATION, ARMONK, NY (US)

(72) Inventors: Ashim Dutta, Clifton Park, NY (US); Chih-Chao Yang, Glenmont (NY); Kamal Rudra, Albany, NY (US); Nilanka W Sirikkathuge, Guilderland, NY (US)

(21) Appl. No.: 19/079,970

(22) Filed: Mar. 14, 2025

(51) Int. Cl. H10W 20/42; H10W 20/00; H10W 20/41

(52) U.S. Cl. CPC H10W 20/42; H10W 20/056; H10W 20/063; H10W 20/435

(57) ABSTRACT

An interconnect includes an underling layer, and a first metal line located on top of the underlying layer. A via is located on top of the first metal line and at least one line divot is located adjacent to via. The at least one-line divot extends downwards into the first metal line.

### BACKGROUND

The present invention generally relates to the field of microelectronic devices, and more particularly to forming interconnects.

Nanosheet is the lead device architecture in continuing CMOS scaling are fabricated on the same chip/wafer as MRAM. Interconnects provide connections to different layers of the device where the manufacturing process can lead to variations of the height.

### BRIEF SUMMARY

Additional aspects and/or advantages will be set forth in part in the description which follows and, in part, will be apparent from the description, or may be learned by practice of the invention.

An interconnect includes an underling layer, and a first metal line located on top of the underlying layer. A via is located on top of the first metal line and at least one line divot is located adjacent to via. The at least one line divot extends downwards into the first metal line.

An interconnect includes an underling layer, and a first metal line located on top of the underlying layer. A first via is located on top of the first metal line and at least one line divot is located adjacent to via. The at least one-line divot extends downwards into the first metal. A second metal line located on top of the underlying layer. A second via is located on top of the second metal line. At least one line divot is located adjacent to the second via and the at least one-line divot extends downwards into the second metal line.

A method includes the steps of forming a Mx metal layer on an underlying layer and forming a first layer on top of the Mx metal layer. Forming a trench within the first layer and the trench exposes a top surface of the Mx metal layer. Forming a top metal layer on top of the first layer in the top metal layer fills the trench. Etching the top metal layer, the first layer, and the Mx metal layer to form a plurality of lines. Subtractively etching the top metal layer to remove it from most locations. Where the subtractive etching of the top metal layer forms a via aligned with location of the trench on one of the plurality of lines. The dimensions of the via differ from the dimensions of the trench, such that line divots are formed in the Mx metal layer from the subtractive etching process.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIGS. 1A and 1B illustrate a top-down view and a cross-section of an interconnect after the initial processing, in accordance with an embodiment of the present invention.

FIGS. 2A and 2B illustrate a top-down view and a cross-section of an interconnect after formation of a lithography stack and forming of an initial via pattern, in accordance with an embodiment of the present invention.

FIGS. 3A and 3B illustrate a top-down view and a cross-section of an interconnect after transferring the initial via pattern into the first layer and the removal of the lithography stack, in accordance with an embodiment of the present invention.

FIGS. 4A and 4B illustrate a top-down view and a cross-section of an interconnect after formation of a top metal layer, in accordance with an embodiment of the present invention.

FIGS. 5A and 5B illustrate a top-down view and a cross-section of an interconnect after patterning of the interconnect to form a plurality of lines, in accordance with an embodiment of the present invention.

FIGS. 6A and 6B illustrate a top-down view and a cross-section of an interconnect after formation of a second lithography stack, in accordance with an embodiment of the present invention.

FIGS. 7A, 7B, and 7C illustrate a top-down view and a cross-sections of an interconnect after substrative etching of the top metal layer, in accordance with an embodiment of the present invention.

FIGS. 8A, 8B, 8C, 8D, 8E, and 8F illustrate different a top-down view scenarios an interconnect after substrative etching of the top metal layer that illustrate different via scenarios, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. A subtractive interconnect that was formed using a top via patterning method has a challenge of maintaining uniform height across the chip and wafer as the line height is controlled by top via etch uniformity. One solution is to use an etch stop layer between a metal line and via, but this creates an interface between top via and the metal line which leads to an increase in the contact resistance.

The present invention is directed towards the formation of interconnects, more specifically forming a via that will be connected to a Mx metal line while the height of the adjacent Mx metal lines are maintained. The present invention provides novel interconnect structure that was formed by a subtractive etching process where the top via is connected to metal line and the height of adjacent metal lines remains constant across chip/wafer. This can be scaled to smaller dimensions for 1 nm technology node and beyond.

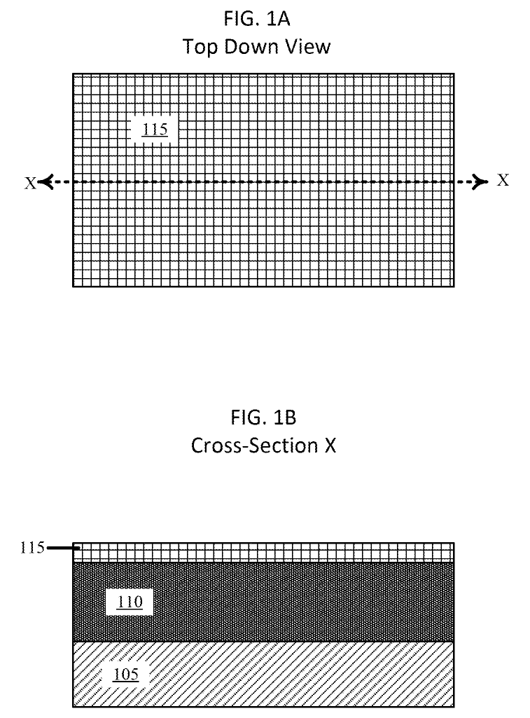

Referring now to FIGS. 1A and 1B, a structure is shown of an interconnect during an intermediate step of forming the initial structure. FIGS. 1A and 1B illustrates an underlying layer 105, a Mx metal layer 110, and a first layer 115. The underlying layer 105 can be a logic device, a passive device, another electronic structure/device, or a substrate. When the underlying layer 105 is a substrate, then the substrate can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of the substrate. In some embodiments, substrate includes both semiconductor materials and dielectric materials. The semiconductor substrate may also comprise an organic semiconductor or a layered semiconductor such as, for example, Si/SiGe, a silicon-on-insulator or a SiGe-on-insulator. A portion or the entire semiconductor substrate may also be comprised of an amorphous, polycrystalline, or monocrystalline. The semiconductor substrate may be doped, undoped or contain doped regions and undoped regions therein.

The Mx metal layer 110 is formed on top of the underlying layer 105. The Mx metal layer 110 can be comprised of Ruthenium (Ru), Copper (Cu), a conductive metal, a conductive alloy, or a combination thereof. The individual metal lines will be subtractively formed from the Mx metal layer 110. The first layer 115 is formed on top of the Mx metal layer 110. The first layer 115 can be comprised of a dielectric layer etch stop layer, for example, SiN, SiOₓ, SiC, etc., or the first layer 115 can be comprised of a metallic etch stop layer, for example, TaN, TiN, etc.

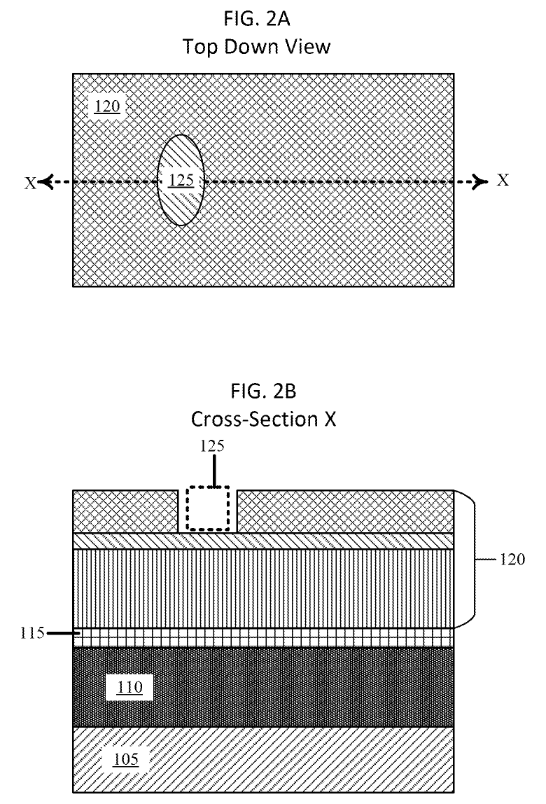

FIGS. 2A and 2B illustrate the processing stage after formation of a lithography stack 120 and forming of an initial via pattern 125. A lithography stack 120 is formed on top of the first layer 115. The lithography stack 120 can be comprised of one or more layers. FIGS. 2A and 2B illustrate that the lithography stack 120 is comprised of three layers. The number of layers of the lithography stack 120 is not meant to be limiting, the use of three layers in the lithography stack 120 is for illustrative purposes only. The lithography stack 120 is patterned to form initial via locations 125, where the initial via trenches 130 will be located. The located of the initial via locations 125 correspond to where one of the plurality of metal lines will be located.

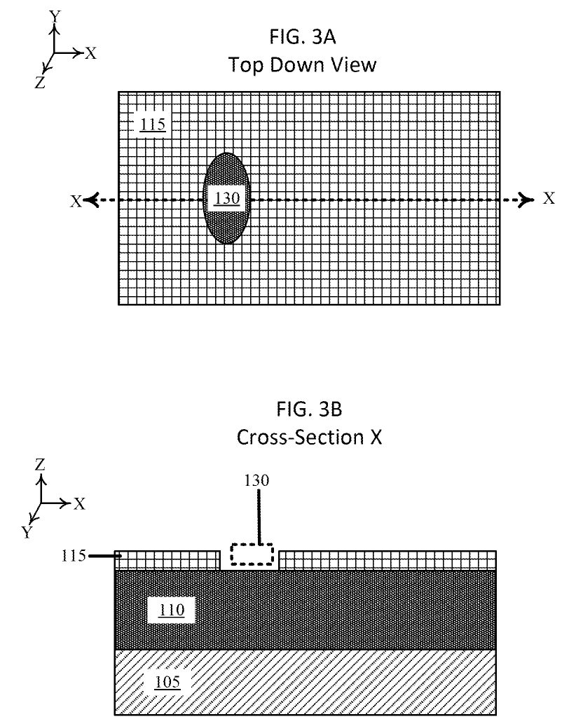

FIGS. 3A and 3B illustrate the processing stage after transferring the initial via pattern 125 into the first layer 115 and the removal of the lithography stack 120. The initial via locations 125 is transferred into the first layer 115 to form the via trench 130. The via trench 130 exposes a top surface of the Mx metal layer 110. The via trench 130 extends in multiple dimensions (along the X-axis, the Y-axis, and the Z-axis).

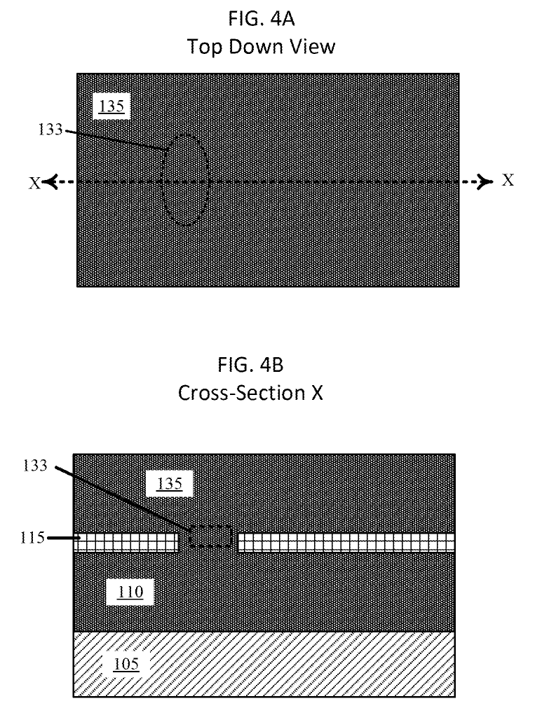

FIGS. 4A and 4B illustrate the processing stage after the formation of the top metal layer 135. A top metal layer 135 is formed on top of the first layer 115 and fills the via trench 130 with material. The filled via trench will be referred to as the connection area 133. Therefore, the top metal layer 135 is connected to the Mx metal layer 110 via connection area 133. The top metal layer 135 can be comprised of Ruthenium (Ru), Copper (Cu), a conductive metal, a conductive alloy, or a combination thereof. The top metal layer 135 can be comprised of the same material as the Mx metal layer 110 or it can be comprised of a different material.

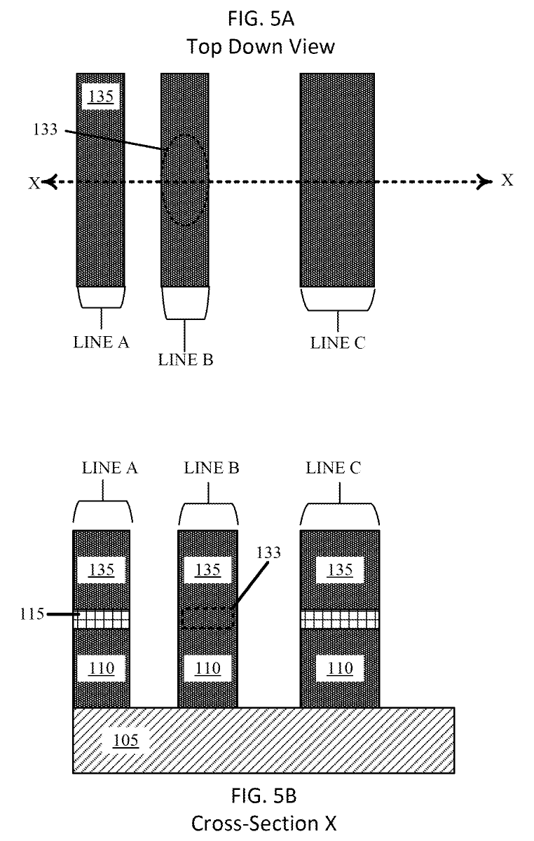

FIGS. 5A and 5B illustrate the processing stage after the pattering of the interconnect to form a plurality of lines, lines A, B, and C. A lithography layer or lithography stack (not shown) is formed on top of the top metal layer 135. The lithography layer or lithography stack (not shown) and the underlying layers are etched to form a plurality of lines. FIGS. 5A and 5B illustrate the formation of line A, line B, and line C. The number of lines form is not meant to be limiting, but at least two or more lines are formed. The connection area 133 is located on one of the lines, the illustrative example has the connection area located in line B. The line that contains the connection area 133 is not meant to be limiting. The connection area 133 could have been located in either line A or line C, or their multiple connection areas 133 could have been formed, where a connection area 133 can be located in each of a plurality of different lines. For example, line A and line B could each have connections areas 133, where the connection areas 133 are aligned with each other or they can be offset from each other. Alternatively, line A and line C could have connections areas 133, where the connection areas 133 are aligned with each other or they can be offset from each other. The connection area 133 is only illustrated in line B to simplify the illustrations and it is not meant to be limiting in any way.

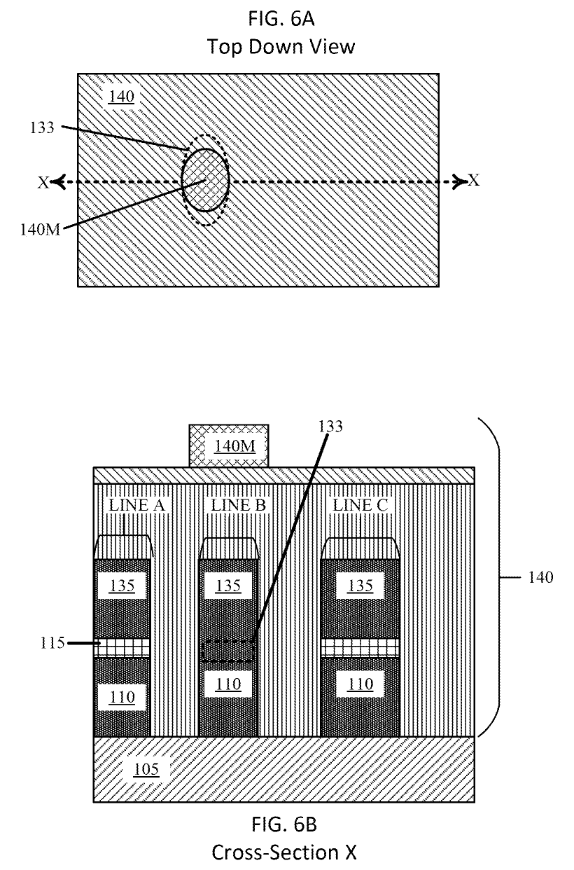

FIGS. 6A and 6B illustrate the processing stage after the formation of a second lithography stack 140. The second lithography stack 140 is formed on top of and around each of the plurality of lines (line A, line B, line C). The second lithography stack 140 can be comprised of one or more layers. FIGS. 6A and 6B illustrate that the second lithography stack 140 is comprised of three layers, where the second lithography stack 140 includes a mask layer 140M. The number of layers of the second lithography stack 140 is not meant to be limiting, the use of three layers in the second lithography stack 140 is for illustrative purposes only. The mask layer 140M is patterned so that the mask layer 140M remains over the connection area 133 (i.e., the opening area that was formed in the first layer 115). The dimensions of the connection are 133 and the mask layer 140M are not perfectly aligned. The dimensions of the mask layer 140M is smaller than the dimensions of the connection area 133 to prevent the formation of an overlap area (e.g., an area where the via 150 will overlap the top surface of the first layer 115).

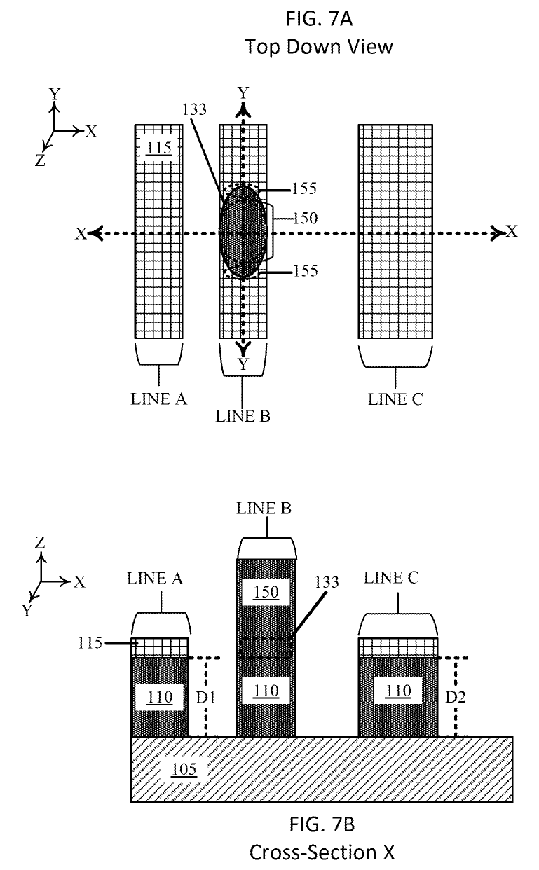

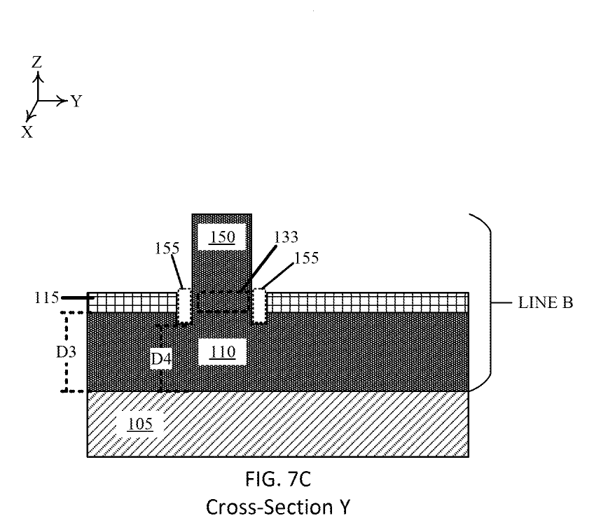

FIGS. 7A, 7B, and 7C illustrate the processing stage after a subtractive etching process was utilized on the top metal layer 135. The subtractive etching process removes most of the top metal layer 135 located on top of the first layer 115 on each of the lines A, B, C. The mask layer 140M prevents some of the material of the top metal layer 135 from being removed. This remining portion of the top metal layer 135 will now be referred to as via 150. Via 150 is connected to the underlying Mx metal layer 110 of line B via connection area 133. FIG. 7C illustrates a cross section along Line B, that illustrates the effects of the different dimensions of the connection area 133 and mask layer 140M. The dimensions of the mask layer 140M do not perfectly match to the connection area 133 (which corresponds to via trench 130). The differences in the dimensions will cause the subtractive etching process to remove some of the Mx metal layer 110 around the connection area 133 to form line divots 155. The line divots 155 are located adjacent to the connection area 133 and the via 150. The first layer 115 prevents the substrative etching processing from etching the Mx metal layer 110 of lines A, B, and C, except for the above-mentioned line divots 155. Therefore, the first layer 115 prevents height variations in the Mx metal layer 110 in each of the lines A, B, C. For example, Mx metal layer 110 of line A has a first height or first dimension D1 the Mx metal layer 110 of line C has a second height or second dimension D2, and Mx metal layer 110 of line B has third height or third dimension D3 (see, FIG. 7C). The first dimension D1, the second dimension D2, and the third dimension D3 are substantially equal to each other. The difference in height Mx metal layer 110 is located adjacent to the via 150 and the connection area 133. The height of the Mx metal layer 110 where the line divots 155 are located is illustrated by the fourth height or dimension D4. The fourth height or dimension D4 is less than the third dimension D3 of the rest of the Mx metal layer 110 of line B. This height or dimension difference D3-D4 illustrates the depth of the line divots 155. The interconnect is additional processed (not shown) to surround each of the plurality of metal lines A, B, C, with a dielectric material (not shown) and electrical contacts (not shown) are formed to connect to via 150.

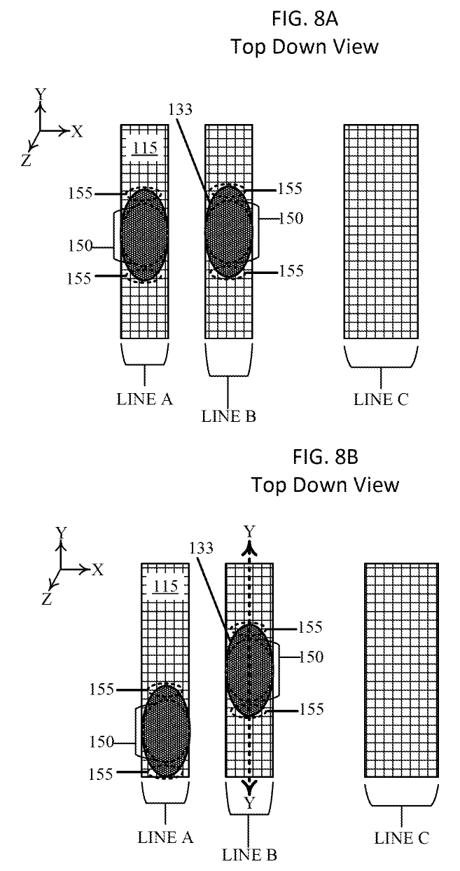

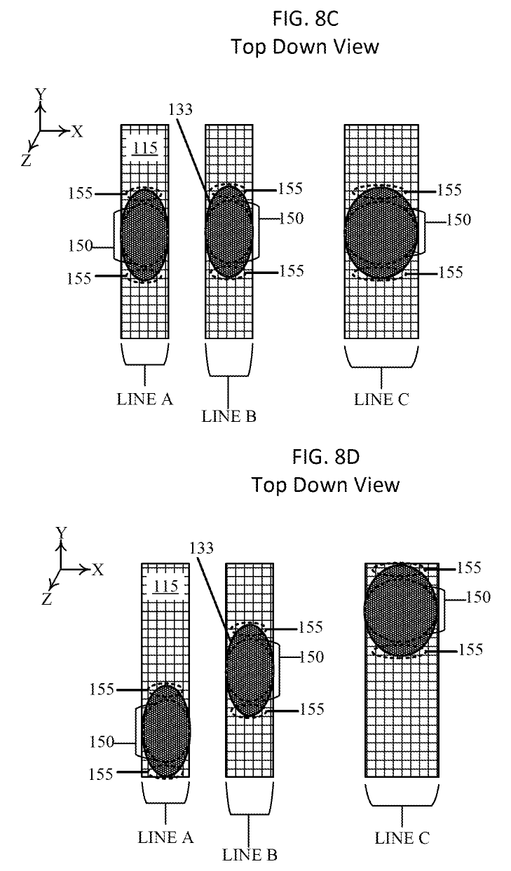

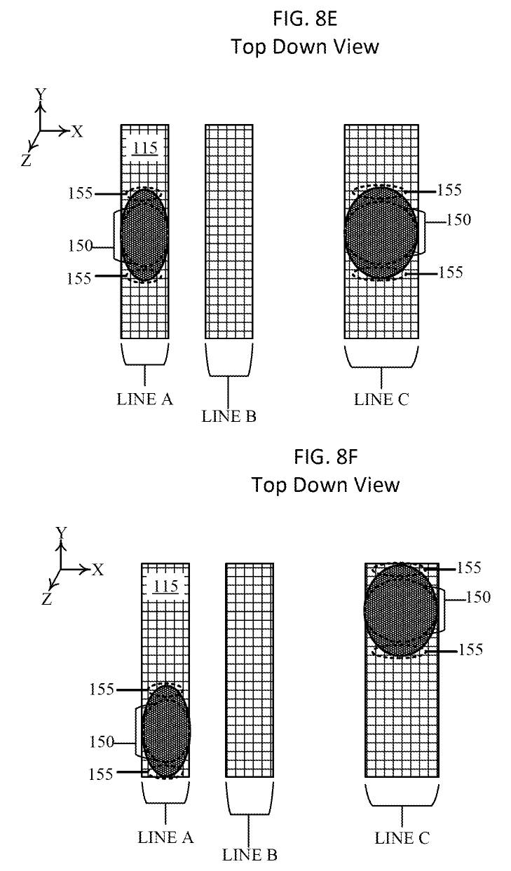

FIGS. 8A, 8B, 8C, 8D, 8E, 8F illustrate different a top-down view scenarios an interconnect after substrative etching of the top metal layer that illustrate different via scenarios. FIG. 8A illustrates the scenario where a via 150 is formed on two adjacent lines (line A and line B) and where the vias 150 are laterally aligned with each other. FIG. 8B illustrates the scenario where a via 150 is formed on two adjacent lines (line A and line B) and where the vias 150 are laterally offset with each other, such that the vias 150 are not substantially horizontally aligned. FIG. 8C illustrates the scenario where a via 150 is formed on three adjacent lines (line A, line B, and line C) and where the vias 150 are laterally aligned with each other. FIG. 8D illustrates the scenario where a via 150 is formed on three adjacent lines (line A, line B, line C) and where the vias 150 are laterally offset with each other, such that the vias 150 are not substantially horizontally aligned. FIGS. 8C and 8D illustrate where the vias 150 are each laterally aligned or offset, but it is well within the skill level of one ordinary skill in the art to mix match the via 150 alignment, such that some of the vias 150 are aligned and some of the vias 150 are offset. FIG. 8E illustrates the scenario where a via 150 is formed on two adjacent lines (line A and line C) and where the vias 150 are laterally aligned with each other. FIG. 8F illustrates the scenario where a via 150 is formed on two adjacent lines (line A and line C) and where the vias 150 are laterally offset with each other, such that the vias 150 are not substantially horizontally aligned.

An interconnect includes an underlying layer 105 and a first metal line (line B) located on top of the underlying layer 105. A via 150 is located on top of the first metal line (Mx metal layer 110 of Line B) and at least one line divot 155 is located adjacent to via 150. The at least one-line divot 155 extends downwards into the first metal line (Mx metal layer 110 of Line B).

The interconnect further includes a second metal line (line A) located on top of the underlying layer 105 and the second metal line (Line A) is located adjacent to the first metal line (line B). The second metal line (Mx metal layer 110 of Line A) has a first height dimension (D1).

The interconnect further includes a third metal line (Line C) located on top of the underlying layer 105 and the third metal line (line C) is located adjacent to the first metal line (line B). The third metal line (Mx metal layer 110 of Line C) has a second height dimension (D2). The first height dimension D1 is substantially equal to the second height dimension D2. The first metal line (Mx metal layer 110 of Line B) has third height dimension (D3, see, for example, FIG. 7C) and the third height dimension D3 is measured at a location that does not include the at least one-line divot 155. The third height dimension D3 is substantially equal to the first height dimension D1 and the second height dimension D3.

The first metal line (Mx metal layer 110 of Line B) has a fourth height dimension D4, and the fourth height dimension D4 is measured from a bottom surface of the at least one line divot 155 to a bottom surface of first metal line (Mx metal layer 110 of Line B, see, for example, FIG. 7C). The third height dimension D3 is greater than the fourth height dimension D4, and the difference between the third height dimension D3 and the fourth height dimension D4 is equal to the depth of the at least one-line divot 155.

An interconnect includes an underlying layer 105 and a first metal line (line B) located on top of the underlying layer 105. A first via 150 is located on top of the first metal line (Mx metal layer 110 of Line B) and at least one line divot 155 is located adjacent to via 150. The at least one-line divot 155 extends downwards into the first metal line (Mx metal layer 110 of Line B). A second metal line (line A) located on top of the underlying layer 105. A second via 155 (see, for example, FIGS. 8A, 8B, 8C, 8D) is located on top of the second metal line (line A). At least one line divot 155 is located adjacent to the second via 150 (see, for example, FIGS. 8A, 8B, 8C, 8D) and the at least one-line divot extends 155 downwards into the second metal line (Mx metal layer 110 of Line A).

The first via 150 located on the first metal line (Line B) is laterally aligned with the second via 150 located on the second metal line (line A) (see, for example, FIG. 8A).

The first via 150 located on the first metal line (Line B) is laterally offset with the second via 150 located on the second metal line (line A) (see, for example, FIG. 8B).

A third metal line (Line C) located on top of the underlying layer 105. A third via 150 is located on top of the third metal line (Mx metal layer 110 of Line C), and at least one line divot 155 is located adjacent to the third via 150. The at least one-line divot 155 extends downwards into the third metal line (Mx metal layer 110 of Line C).

The first via 150 located on the first metal line (Line B) is laterally aligned with the second via 150 located on the second metal line (Line A) and laterally aligned with the third via 150 located on the third metal line (Line C) (see, for example, FIG. 8C).

The first via 150 located on the first metal line (Line B) is laterally offset with the second via 150 located on the second metal line (Line A) (see, for example, FIG. 8D). The first via 150 located on the first metal line (Line B) is laterally offset with the third via 150 located on the third metal line (Line C) (see, for example, FIG. 8D), and the second via 150 located on the second metal line (Line B) is laterally offset with the third via 150 located on the third metal line (Line C) (see, for example, FIG. 8D).

A method includes the steps of forming a Mx metal layer 110 on an underlying layer 105 and forming a first layer 115 on top of the Mx metal layer 110. Forming a trench 130 within the first layer 115 and the trench 130 exposes a top surface of the Mx metal layer 115. Forming a top metal layer 135 on top of the first layer 115 in the top metal layer 135 (i.e., connection area 133) fills the trench 125. Etching the top metal layer 135, the first layer 115, and the Mx metal layer 110 to form a plurality of lines (line A, line B, line C). Subtractively etching the top metal layer 135 to remove it from most locations. Where the subtractive etching of the top metal layer 135 forms a via 150 aligned with location of the trench 130 on one of the plurality of lines (line B). The dimensions of the via 150 differ from the dimensions of the trench 130, such that line divots 155 are formed in the Mx metal layer 110 (of line B) from the subtractive etching process.

Where a first metal line (line A) of the plurality of metal lines (lines A, B, C) that is located adjacent to a metal line (line B) of the plurality of metal lines (lines A, B, C) that includes the via 150. Where the first metal line (line A) has a first height dimension D1.

Where second metal line (line C) of the plurality of metal lines (lines A, B, C) that is located adjacent to the metal line (line B) of the plurality of metal lines (lines A, B, C) that includes the via 150. Where the second metal line (line C) has a second height dimension D2. Where the first height dimension D1 is substantially equal to the second height dimension D2.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An interconnect comprising:
an underling layer;
a first metal line located on top of the underlying layer, wherein a via is located on top of the first metal line, wherein at least one line divot is located adjacent to via, wherein the at least one-line divot extends downwards into the first metal line.

2. The interconnect of claim 1, further comprising:
a second metal line located on top of the underlying layer, wherein the second metal line is located adjacent to the first metal line.

3. The interconnect of claim 2, wherein the second metal line has a first height dimension.

4. The interconnect of claim 3, further comprising:
a third metal line located on top of the underlying layer, wherein the third metal line is located adjacent to the first metal line.

5. The interconnect of claim 4, wherein the third metal line has a second height dimension.

6. The interconnect of claim 4, wherein the first height dimension is substantially equal to the second height dimension.

7. The interconnect of claim 6, wherein the first metal line has third height dimension, wherein the third height dimension is measured at a location that does not include the at least one-line divot.

8. The interconnect of claim 7, wherein the third height dimension is substantially equal to the first height dimension and the second height dimension.

9. The interconnect of claim 8, wherein the first metal line has a fourth height dimension, wherein the fourth height dimension is measured from a bottom surface of the at least one-line divot to a bottom surface of first metal line.

10. The interconnect of claim 9, wherein the third height dimension is greater than the fourth height dimension, wherein the difference between the third height dimension and the fourth height dimension is equal to the depth of the at least one-line divot.

11. An interconnect comprising:
an underling layer;
a first metal line located on top of the underlying layer, wherein a via is located on top of the first metal line, wherein at least one line divot is located adjacent to the to via, wherein the at least one-line divot extends downwards into the first metal line; and
a second metal line located on top of the underlying layer, wherein a second via is located on top of the second metal line, wherein at least one line divot is located adjacent to the second via, wherein the at least one-line divot extends downwards into the second metal line.

12. The interconnect of claim 11, wherein the first via located on the first metal line is laterally aligned with the second via located on the second metal line.

13. The interconnect of claim 11, wherein the first via located on the first metal line is laterally offset with the second via located on the second metal line.

14. The interconnect of claim 11, further comprising
a third metal line located on top of the underlying layer, wherein a third via is located on top of the third metal line, wherein at least one line divot is located adjacent to the third via, wherein the at least one-line divot extends downwards into the third metal line.

15. The interconnect of claim 14, wherein the first via located on the first metal line is laterally aligned with the second via located on the second metal line and laterally aligned with the third via located on the third metal line.

16. The interconnect of claim 14, wherein the first via located on the first metal line is laterally offset with the second via located on the second metal line, wherein the first via located on the first metal line is laterally offset with the third via located on the third metal line, and wherein the second via located on the second metal line is laterally offset with the third via located on the third metal line.

17. A method comprising:
forming a Mx metal layer on an underlying layer;
forming a first layer on top of the Mx metal layer;
forming a trench within the first layer, wherein the trench exposes a top surface of the Mx metal layer;
forming a top metal layer on top of the first layer, wherein the top metal layer fills the trench;
etching the top metal layer, the first layer, and the Mx metal layer to form a plurality of lines;
subtractively etching the top metal layer to remove it from most locations, wherein the subtractive etching of the top metal layer forms a via aligned with location of the trench on one of the plurality of lines, wherein the dimensions of the via differ from the dimensions of the trench, such that line divots are formed in the Mx metal layer from the subtractive etching process.

18. The method of claim 17, wherein a first metal line of the plurality of metal lines that is located adjacent to a metal line of the plurality of metal lines that includes the via, wherein the first metal line has a first height dimension.

19. The method of claim 18, wherein a second metal line of the plurality of metal lines that is located adjacent to the metal line of the plurality of metal lines that includes the via, wherein the second metal line has a second height dimension.

20. The method of claim 19, wherein the first height dimension is substantially equal to the second height dimension.
